(19) United States
(12) Patent Application Publication
(10) Pub. No.: US 2003/0138709 A1
(43) Pub. Date: Jul. 24, 2003

(54) Wafer fabrication having improved laserwise alignment recovery

(76) Inventors: Daniel P. Burbank, Minneapolis, MN (US); Kenneth P. Naughton, Minneapolis, MN (US)

Correspondence Address: Deirdre Megley Kvale, Westman, Champlin & Kelly, Suite 1600, International Centre, 900 Second Avenue South, Minneapolis, MN, 55402-3319, US

(21) Appl. No.: 10/291,228

(22) Filed: Nov. 8, 2002

Related U.S. Application Data
(60) Provisional application No. 60/338,795, filed on Nov. 9, 2001.

(51) Int. Cl. G03F 9/00; G03C 5/00; G01B 11/00

(52) U.S. Cl. 430/22; 430/296; 356/400; 356/401; 430/942

(57) ABSTRACT

A recovery system for recovering alignment marks obscured by a deposited obscuring layer. The system includes an imaging system to locate the obscured alignment marks. The located alignment marks are recovered through the obscuring layer to use the alignment marks to align patterned layers of a fabricated structure.

### CROSS-REFERENCE TO RELATED APPLICATION

This application claims priority from U.S. Provisional Application 60/338,795 filed on Nov. 9, 2001 and entitled “ALIGNMENT MARK RECOVERY BY LOCALIZED REMOVAL OF OBSCURING THIN FILM”.

### FIELD OF THE INVENTION

The present invention relates generally to registration for fabricating electro, electromechanical structures or integrated circuits, and more particularly but not by limitation to an alignment mark recovery for fabrication.

### BACKGROUND OF THE INVENTION

Microchip fabrication techniques for fabricating integrated circuits, microelectro-mechanical structures (MEMS) generally include multiple process steps to form the completed assembly. The process steps include layerwise deposition of multiple patterned layers on a wafer substrate. The patterned layers are formed using known deposition, etching or photolithography techniques and must be accurately aligned to fabricate the features or components of the structure. Alignment of multiple fabrication layers using wafer coordinates or edge reference positions does not provide precision control.

Alignment marks deposited on an inner portion of the wafer spaced from an edge portion of the wafer used to align patterned layers can be obscured by a deposited layer. For example the alignment marks can be obscured by a deposited layer, such as a metal or polymer layer which has a planar surface. Prior processes for recovering alignment marks use course positioning and photolithographic masking and etching techniques to remove the obscuring layer proximate to the area of the alignment mark. These recovery processes require multiple process steps increasing complexity and cost of the fabrication process. Embodiments of the present invention provide solutions to these and other problems, and offer other advantages over the prior art.

### SUMMARY OF THE INVENTION

The present invention relates to a recovery system for recovering alignment marks obscured by a deposited obscuring layer. The system includes an imaging system to locate the obscured alignment marks. As described, the imaging system uses a reflected electron image to locate the obscured alignment marks through the obscuring layer. The located alignment marks are recovered through the obscuring layer for use to align patterned layers of a fabricated structure. Other features and benefits that characterize embodiments of the present invention will be apparent upon reading the following detailed description and review of the associated drawings.

### BRIEF DESCRIPTION OF THE DRAWINGS

FIG. 1 is a schematic illustration of an obscured alignment marks on a fabrication structure.

FIG. 2 is a schematic illustration of an imaging system for locating obscured alignment marks for a fabrication process.

FIG. 3 is a schematic illustration of an embodiment of an imaged portion of a wafer to locate obscured alignment marks.

FIG. 4 is a schematic illustration of an embodiment of an ablating system to recovery an obscured alignment mark.

FIG. 5 is a schematic illustration of an embodiment of a feedback system for etching control.

FIG. 6 is a schematic illustration of an embodiment of an alignment mark recovery system including an electron microscope and focused ion beam (FIB).

FIG. 7 is a schematic illustration of an embodiment of an alignment recovery system in a vacuum chamber.

FIGS. 8-9 schematically illustrate an embodiment of a recovery system for alignment marks through a localized opening in a deposited obscuring layer.

FIG. 10 is a flow chart illustrating an embodiment of process steps for recovering alignment marks.

### DETAILED DESCRIPTION OF ILLUSTRATIVE EMBODIMENTS

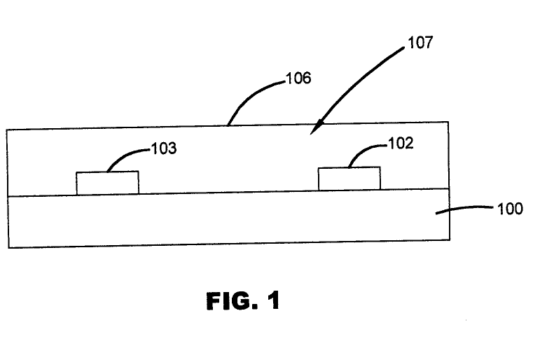

Fabrication process steps for semiconductor, integrated circuits, read/write transducers or MEMS involve alignment of multiple patterned depositions or layers on a wafer or substructure 100. As schematically shown in FIG. 1, registration or alignment marks 102 are used to align patterned layers to form an integrated structure. During fabrication, the alignment marks 102 can be obscured by an obscuring layer or film 104 having a planarized surface 106 so that the alignment marks 102 are not visible to form a patterned structure or layer. In particular, as illustrated in FIG. 1, the obscuring layer 104 includes a planarized surface which can be formed using known chemical mechanical processing techniques (CMP). In particular, the obscuring layer 104 can be planarized or deposited on a planarized surface obscuring the alignment marks 102.

Prior processes for recovering obscured alignment marks to align patterned layers for an integrated structure employ course positioning and known photolithography process steps to recover obscured alignment marks. In particular, prior recovery processes include multiple process steps including a photoresist mask formed using course positioning techniques which typically involve wafer coordinates or a flat reference edge of the wafer. The photoresist mask is used to etch a window or area proximate to the alignment mark. The course positioning requires a larger etched area or window to recover the marks and the photolithographic process steps require deposition of a mask or photoresist layer to form the mask and subsequent etching and stripping process steps which increases fabrication process steps. Further, the recovery steps are repeated for multiple fabrication layers increasing fabrication complexity and expense.

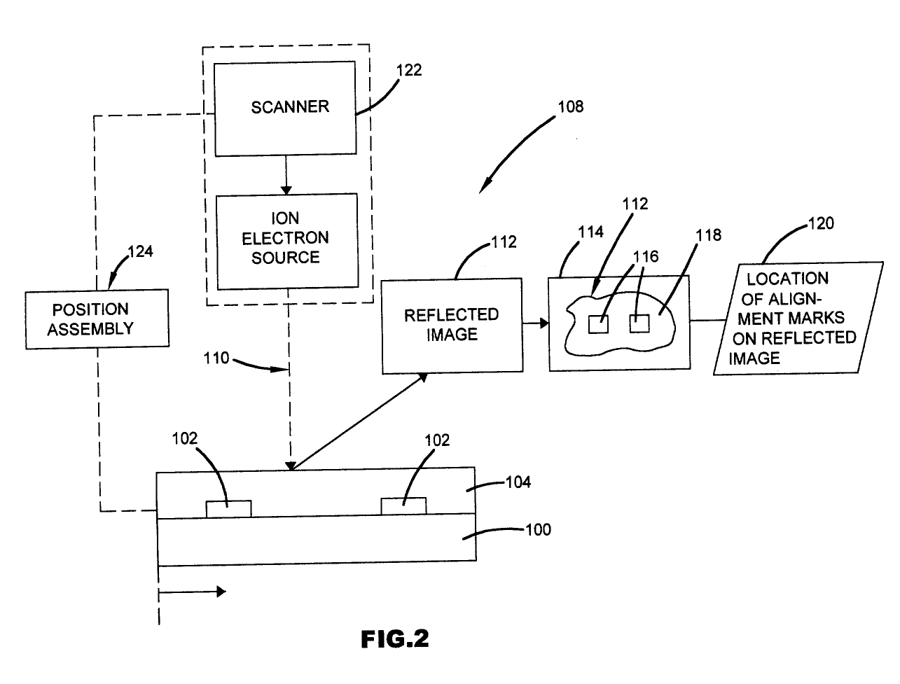

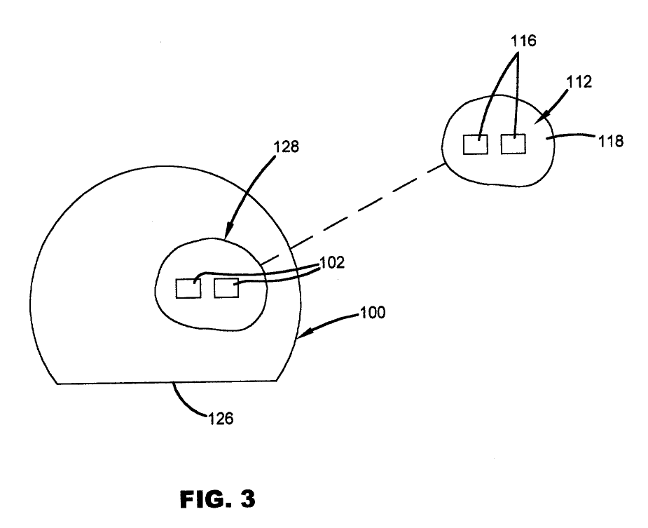

The present invention provides a simple recovery process to reduce manufacturing complexity with increased precision and reduced complexity. FIGS. 2-3 schematically illustrates a recovery embodiment for alignment marks 102 obscured by an opaque material where like numbers are used to refer to like numbers in the previous FIGS. The system includes an imaging system 108 to locate obscured alignment marks 102 through the obscuring layer 104. As shown in FIG. 2, the obscuring layer 104 or structure is scanned using an electron or ion beam 110 or scanning electron microscope (SEM) to image the obscuring layer.

The imaging system captures a digital image of the wafer below the surface of the obscuring layer 104 as illustrated by block 112. The digital reflected image 112 is processed as illustrated by block 114 to isolate a reflected image of the alignment marks 116 from a background portion 118 of the reflected image. The reflected image of the alignment marks 116 below the obscuring layer is different from the reflected image below the obscuring layer without the alignment marks because the ion beam or electron reflection is different due to atomic differences of the materials.

Thus the alignment marks can be isolated from the background image to output a location or position of the alignment marks relative to the reflected image as illustrated by block 120. Scanner 122 moves the imaging beam 110 over the surface of the obscuring layer 104. As illustrated schematically, a position assembly 124 controls the relative position of the imaging and the wafer or substructure 100 so that the alignment marks can be located relative to the position of the ion beam 110 on the surface of the wafer or substructure 100 and the position of the alignment marks 116 on the reflected image 112.

In particular as illustrated in FIG. 3, wafer or substructure 100 includes a reference surface or position 126. In the illustrated embodiment, the position assembly 124 uses the reference surface or position 126 to locate an image area 128 on the wafer 100. The reflected image 118 of the image area 128 is processed to locate alignment mark 116 on the reflected image 118 of the image area 128 and the position of the reflected image of the alignment marks 116 is used to locate the position of the alignment marks 102 on the wafer or substructure 100 based upon the location of the imaged area 128 on the wafer.

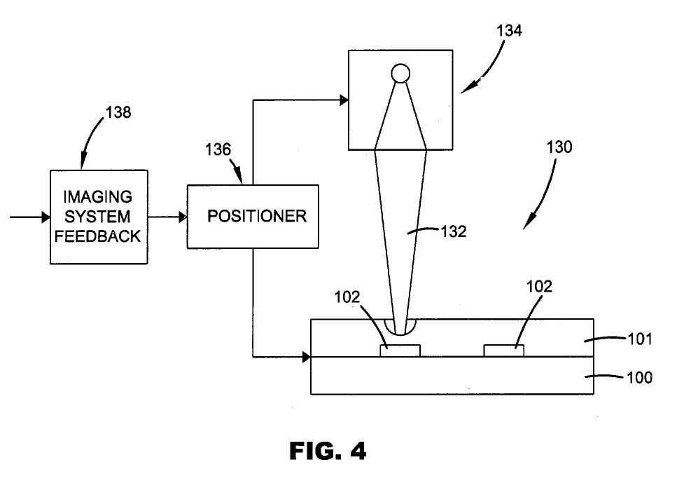

As illustrated in FIG. 4, the process or system includes a recovery system 130 to recover the located alignment marks 102 by removing a localized portion of the obscuring layer covering the alignment marks 102. In the embodiment of FIG. 4, a focused beam 132 from an energy source 134 forms an ablating system to ablate or etch the obscuring material to recover the alignment mark 102. As shown a positioner 136 is coupled to the wafer or substructure 100 and the energy source 134 to focus the beam 132 over the alignment marks 100 based upon feedback from the imaging system 108 as illustrated schematically by block 138. The beam or energy source can be a focused ion beam, a collimated ion beam or excimer laser to remove the obscuring material or layer. Thus, as described, the system provides a fabrication process to locate and recover alignment marks which does not require multiple photolithographic process steps nor rely on course positioning to recover the alignment marks.

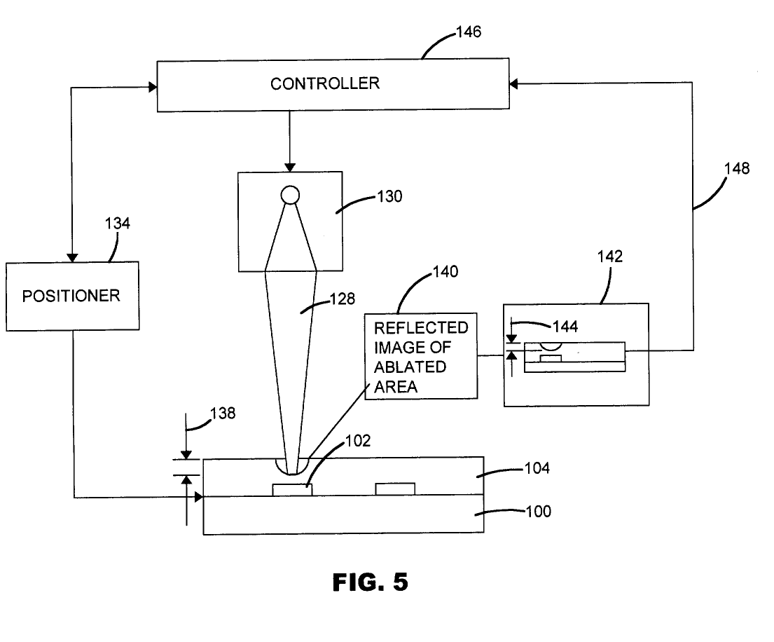

FIG. 5 illustrates an embodiment of a recovery process to remove obscuring material including image feedback control to control an etch depth for operation of the ablating system. The etch depth is coarsely controlled based upon a thickness of the deposited obscuring layer 104, depth of the alignment mark 102 and the etching rate of the material. In the embodiment illustrated in FIG. 5 where like numbers are used to refer to like parts in the previous FIGS., a reflected image of the ablated area as illustrated schematically by block 140 is captured by an imaging system and the digital image is processed as illustrated by block 142 to monitor an etch depth 144. A controller 146 receives feedback as illustrated by line 148 of the processed image of the ablated area 142 to operate the ablating system to control the etch or removal depth of material, which is referred to as “end point detection”. This limits damage to the alignment marks or structure for subsequent processing.

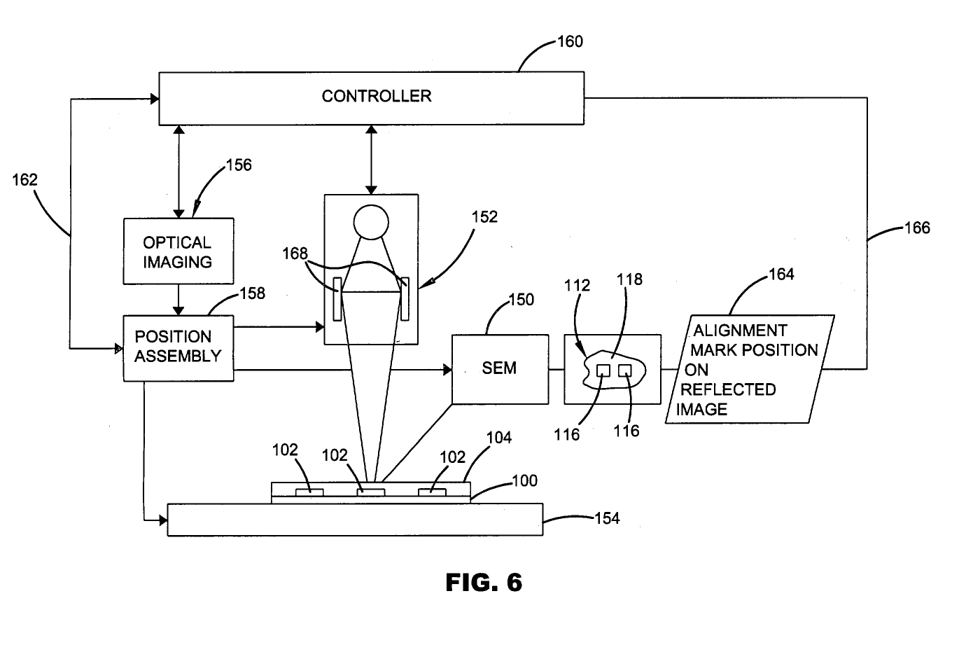

FIG. 6 schematically illustrates a recovery system embodiment including a scanning electron microscope SEM 150 and a focused ion beam (“FIB”) 152 to provide an imaging mode and an ablating mode. In the embodiment shown, the wafer or substructure 100 is supported on a platform 154 and the system includes an optical imager 156 and a position assembly 158 to locate or position the SEM 150 and FIB 152 relative to the surface of the wafer as schematically illustrated. In particular, in the imaging mode, the optical imager 156 and position assembly 158 locates the SEM 150 relative to optically visible reference positions (e.g. edge surface 126 shown in FIG. 3) on the wafer 100 for imaging. A controller 160 receives position feedback 162 for the relative position of the SEM 150 on the surface of the wafer 100 based upon information from the optical imager 156 and the position assembly 158 as schematically illustrated.

The SEM 150 captures and processes a reflected image 112 to locate the obscured alignment marks 116 on the reflected image 112. Feedback information regarding the location of the alignment mark 116 on the reflected image 112 as illustrated by block 164 is provided to the controller 160 as illustrated by line 166 to locate the position of the alignment mark 102 on the wafer 100 based upon the area of the wafer imaged and the location of the alignment mark 116 on the reflected image 112.

In the ablating mode, the FIB 152 focuses an ion beam on the surface of the wafer 100 to etch to remove the material obscuring the alignment mark 102. FIB 152 is positioned on the wafer 100 by the position assembly 158 based upon alignment mark position feedback from the imaging system as illustrated by line 166 to provide localized material removal for alignment mark recovery. In the illustrated embodiment, FIB 152 radiates an ion beam which is focused using an electromagnetic structure as illustrated by blocks 168 although application is not limited to the FIB 152 structure shown.

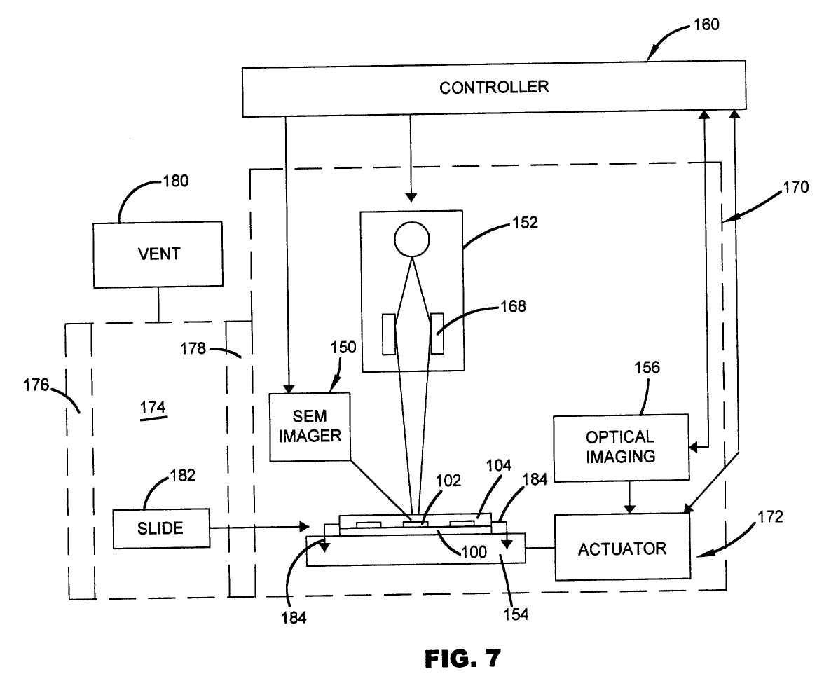

FIG. 7 illustrates an embodiment of the recovery system where like numbers are used to refer to like parts in the previous FIGS. The system includes SEM 150 and FIB 152 which are contained in a vacuum chamber 170 to prevent ambient atmosphere from interfering with the FIB 152 and SEM 150. In the illustrated embodiment, wafer or substructure 100 is supported on platform 154 and the positioner includes an actuator 172 coupled to the platform 154 to move the platform 154 to position the wafer relative to the SEM 150 and FIB 152 which are stationarily supported in the vacuum chamber 170. The optical imager 156 provides a reference location to control operation of the actuator 172 to position the platform 154 (and wafer 100) relative to the SEM 150 and FIB 152 to recover the alignment mark 102.

The wafer or substrate 100 is loaded into the vacuum chamber 170 through an air lock interface chamber 174 illustrated diagrammatically. The interface chamber 174 includes inner and outer sealed doors 176, 178 and is vented as illustrated by block 180. For fabrication the workpiece or wafer is loaded into the interface chamber 174 through outer door 172 while maintaining the inner door 178 closed to isolate chamber 170. Thereafter, outer door 176 is closed and the chamber is vented as illustrated by block 180 to provide a vacuum chamber. The workpiece or wafer is transferred into chamber 170 through the inner sealed door 178 while the outer door 176 remains closed. The wafer or workpiece is transferred into the chamber 170 by a slide 182 illustrated schematically which moves the workpiece or wafer 100 from the interface chamber 174 to platform 154. The slide 182 and the inner door 178 are remotely controlled so that inner door 178 opens and the slide 182 transports the workpiece while the outer door 176 is closed to maintain the vacuum environment. In the illustrated embodiment, the workpiece is secured to the platform via an electrostatic chuck or alternate clamping mechanisms 184 as diagrammatically shown.

As described, the beam of the ablating system forms a localized opening in the obscuring layer 104 so that the alignment marks are visible therethrough. The visible alignments can be located to form a patterned structure in the deposited obscuring layer 104 or alternate layers. In particular, the obscuring layer 104 can be a metal or polymer layer or other opaque or obscuring fabrication layer (or non-photoresist layer). The layer is patterned using standard photolithography or other techniques to form the integrated structure.

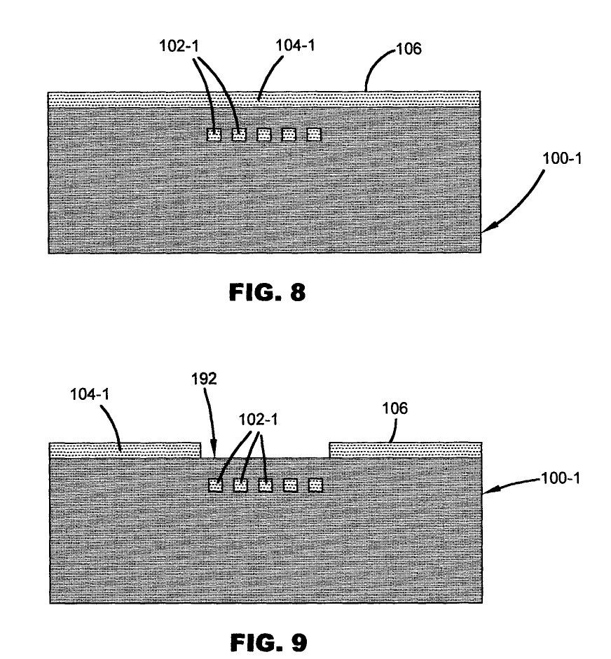

In the embodiment illustrated in FIGS. 8-9 the alignment marks are embedded in a substructure below a planarized surface of the substructure 100-1 and the obscuring layer 104-1 is deposited thereon. As previously described, the obscuring layer 104-1 is formed of a fabrication layer which is patterned to form the integrated structure. For fabrication of the obscuring layer 104-1, the embedded alignment marks 102-1 are imaged through the obscuring layer 104-1 to locate the alignment marks 102-1 to remove a localized portion 192 of the obscuring layer 104-1 to recover the alignment marks 102-1. The embedded location of the alignment marks 102-1 limit damage to the alignment marks during localized removal or recovery of the alignment marks through the obscuring layer 104-1. The embedded alignment marks are visible through the non-opaque or non-obscuring substructure to align a patterned structure or layer.

As described in the present invention, the alignment marks 104 are recovered using an imaging system which locates the obscured alignment marks through the obscuring layer 104 using a reflected electron image. The alignment marks 102 are recovered by localized removal of the material obscuring the alignment marks 104. The recovered alignment marks 102 are used to pattern the obscuring layer 104, or other layers, by known patterning techniques, such a photolithography or other techniques. For example, the obscuring layer 104 is patterned by depositing a photoresist layer or mask on the obscuring layer. The photoresist layer is exposed and the obscuring layer is etched to form the patterned structure. In the illustrated embodiment, the alignment marks 102-1 are embedded in an Alumina Al₂O₃ layer on a wafer or substrate such as SiO₂ or AL₂O₃-TiC wafer or substrate of a read/write head, although application is not limited to the particular embodiments illustrated.

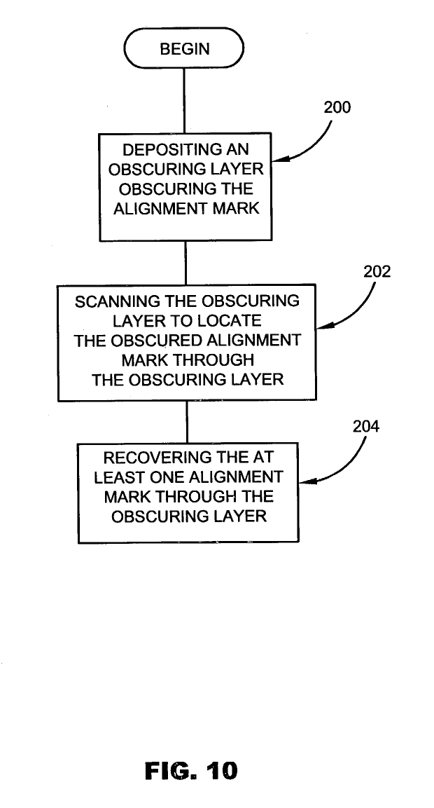

As illustrated in FIG. 10, to recover obscured alignment marks which are obscured by a deposited obscuring layer as illustrated in block 200, the structure is scanned to locate the obscured alignment mark through the obscuring layer as illustrated by block 202 using an electron imaging device or microscope. The alignment mark 102 is recovered through the obscured layer as illustrated by block 204 so that the alignment mark 102 is visible to align a patterned layer of a fabricated structure.

A recovery system for recovering alignment marks (such as 102) obscured by a deposited obscuring layer (such as 104). The system includes an imaging system (such as 108) to locate the obscured alignment marks using a reflected electron image (such as 112) from or through the obscuring layer 104 to locate the obscured alignment marks. The located alignment marks are recovered through the obscuring layer 104 to use the alignment marks to align patterned layers of a fabricated structure.

It is to be understood that even though numerous characteristics and advantages of various embodiments of the invention have been set forth in the foregoing description, together with details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. For example, the particular elements may vary depending on the particular application while maintaining substantially the same functionality without departing from the scope and spirit of the present invention. In addition, although the preferred embodiment described herein is directed to a particular application, it will be appreciated by those skilled in the art that the teachings of the present invention can be applied to various micro-fabrication structures, without departing from the scope and spirit of the present invention.

What is claimed is:

1. A method of fabricating a patterned structure comprising steps of:
depositing an obscuring layer having a planarized surface obscuring at least one alignment mark on a substructure;
imaging the substructure to locate the at least one alignment mark through the obscuring layer; and
recovering the at least one alignment mark by removing a localized portion of the obscuring layer obscuring the at least one alignment mark located by imaging the substructure.

2. The method of claim 1 wherein the step of imaging uses a scanning electron microscope or ion or electron beam.

3. The method of claim 1 wherein the step of imaging to locate the at least one obscured alignment mark locates the at least one alignment mark using atomic differences between a portion of the substructure below the obscuring layer with the at least one alignment mark and a portion of the structure below the obscuring layer without the at least one alignment mark.

4. The method of claim 1 wherein the step of imaging the obscuring layer comprises:
scanning the obscuring layer with a beam of particles;
capturing a reflected image of the particles;
processing the reflected image to isolate a reflected image of the at least one alignment mark from a background portion of the reflected image; and
determining a location of the reflected image of the at least one alignment mark.

5. The method of claim 1 wherein the step of recovering the at least one alignment mark through the obscuring layer comprises:
focusing an energy beam on the localized portion of the obscuring layer obscuring the at least one alignment mark to remove the localized portion of the obscuring layer obscuring the at least one alignment mark.

6. The method of claim 1 wherein the obscuring layer is etched to remove the localized portion of the obscuring layer and further comprising the step of:
controlling an etching depth using a feedback image of an etching area.

7. The method of claim 1 wherein the substructure includes a planarized surface upon which the obscuring layer is deposited and further comprising the step of:
embedding the at least one alignment mark in the substructure prior to depositing the obscuring layer thereon.

8. The method of claim 1 and further comprising the step of:
forming a fabricated pattern in the obscuring layer using the at least one recovered alignment mark.

9. The method of claim 8 wherein the step of forming the fabricated pattern in the obscuring layer comprises:
depositing a photoresist layer on the obscuring layer;
exposing the photoresist layer using the at least one recovered alignment mark; and
etching the obscuring layer to form the fabricated pattern.

10. The method of claim 1 wherein the obscuring layer is an opaque material.

11. A patterned structure formed according to the method steps of claim 1.

12. The patterned structure of claim 11 wherein the patterned structure is one of a read/write head for a data storage device, an integrated circuit, or micro electro-mechanical system (MEMS).

13. An apparatus for recovering an alignment mark on a fabrication structure obscured by an obscuring layer comprising;
a platform to support the fabrication structure;
an imaging device to locate an alignment mark through a obscuring layer having a planarized surface;
a processor coupled to the imaging device to locate the alignment mark through the obscuring layer;
an ablating device energizable to focus an energy beam relative to the platform to remove a localized portion of the obscuring layer obscuring the located alignment mark; and
a positioner to align the platform, the ablating device and the imaging device to locate the obscured alignment mark through the obscuring layer and remove the localized portion of the obscuring layer obscuring the located alignment mark.

14. The apparatus of claim 13 wherein the imaging device locates the alignment mark using atomic differences for a portion of the structure below the obscuring layer with the alignment mark and a portion of the structure below the obscuring layer without the alignment mark.

15. The apparatus of claim 13 wherein the imaging device includes a scanning electron microscope.

16. The apparatus of claim 13 wherein the ablating device is a FIB.

17. The apparatus of claim 13 and further comprising a controller coupled to the ablating device to control a removal depth of the obscuring layer based upon a feedback image of an ablating area.

18. A method for fabricating a structure comprising steps of:
forming a substructure having at least one alignment mark embedded below a planarized surface of the substructure;
depositing an obscuring layer over the substructure obscuring the at least one alignment mark;
imaging the structure to locate the at least one alignment mark through the obscuring layer; and
forming a localized opening in the obscuring layer to recover the alignment mark through the obscuring layer.

19. The method of claim 18 and further comprising the step of:
forming a pattern in the obscuring layer using the recovered alignment mark.

20. The method of claim 19 wherein the step of forming the pattern in the obscuring layer comprises:
locating the embedded alignment mark below the planarized surface of the substructure.

21. The method of claim 18 wherein the step of forming the localized opening in the obscuring layer uses a focused ion beam.

22. A method for fabricating a patterned structure comprising steps of:
depositing an obscuring layer formed of an opaque material obscuring at least one alignment mark on a substructure;
imaging the substructure to locate the at least one alignment mark through the obscuring layer; and
removing a localized portion of the obscuring layer obscuring the at least one alignment mark to recover the obscured alignment mark.

23. The method of claim 22 and further comprising the step of:
detecting the recovered alignment mark and patterning the obscuring layer using the detected alignment mark.

24. The method of claim 22 and further comprising the step of:
controlling a removal depth of the obscuring layer using a feedback image of an etching area.
